(19) United States
(12) Patent Application Publication
(10) Pub. No.: US 2026/0173318 A1
(43) Pub. Date: Jun. 18, 2026

(54) LIQUID COOLING DEVICE

(71) Applicant: OVH, Roubaix (FR)

(72) Inventors: Ali CHEHADE, Moncheaux (FR); Henryk KLABA, Roubaix (FR); Mohamad HNAYNO, La Madeleine (FR)

(21) Appl. No.: 19/412,032

(22) Filed: Dec. 8, 2025

(30) Foreign Application Priority Data
Dec. 18, 2024 (EP) 24307174.3

(51) Int. Cl. H05K 7/20

(52) U.S. Cl. CPC H05K 7/20327; H05K 7/20454

(57) ABSTRACT

A liquid cooling device for mounting onto a heat-generating electronic component submerged in an immersion cooling liquid, is presented. The cooling device body having a first surface disposed on a bottommost side for mounting onto an upper surface of the electronic component in which the first surface is configured with a open recess formed along an outer periphery of the first surface, a thermal interface material (TIM) interposed between the first surface and the upper surface of the electronic component, and a resiliently deformable gasket mounted on, and seated within, the open recess along the outer periphery of the first surface. The gasket configured to deformably expand horizontally or vertically to establish a protective fluid-proof seal for the first surface of the cooling device body, the upper surface of the electronic component, and the TIM from the immersion cooling liquid.

### CROSS-REFERENCE

The present patent application claims priority to European Patent Application Number 24307174.3 filed on Dec. 18, 2024, the disclosure of which is hereby incorporated by reference herein in its entirety.

### TECHNICAL FIELD

The present technology relates to liquid cooling devices for cooling heat-generating electronic components in computing infrastructures, such as, water blocks.

### BACKGROUND

Electronic equipment, for example servers, memory banks, computer discs, and the like, is conventionally grouped in equipment racks. Large data centers and other large computing infrastructures may contain thousands of racks supporting thousands or even tens of thousands of servers and other electronic equipment.

The electronic equipment mounted in the racks consumes large amounts of electric power and generates significant amounts of heat. Cooling needs are important in such racks. Some electronic equipment, such as processors, generate so much heat that they could fail within seconds in case of a lack of cooling. Moreover, with advancing technological progress, electronic equipment for computing purposes is not only becoming more performant but also has a greater associated thermal design power (TDP) (i.e., a maximum amount of heat generated thereby which a cooling system should dissipate) thus emphasizing the need to improve cooling solutions.

Forced air-cooling has been traditionally used to disperse heat generated by such electronic equipment mounted in the racks. Air-cooling requires the use of powerful fans, and the provision of space between the electronic equipment or between electronic components of a given electronic equipment. The space is used for placing heat sinks and for allowing sufficient airflow. However, such forced air-cooling methods are generally not very efficient.

Liquid cooling technologies are increasingly used as a more efficient and cost-effective solution to maintain reliable operating temperatures of electronic equipment, such as servers, mounted in racks. Liquid cooling technologies include liquid immersion systems and water cooling channeling systems.

Liquid immersion systems typically comprise submerging the electronic equipment including the heat-generating electronic component(s) (e.g., server processor) in an immersion cooling liquid, which is a thermally conductive liquid that operates to remove heat from the heat-generating electronic component(s). Typically, the immersion cooling liquids comprise dielectric liquids containing hydrocarbons and/or fluorocarbons.

Water cooling channeling systems comprise water blocks that are mounted atop of the heat-generating electronic component(s). The water blocks incorporate an internal conduit that channels cooling water therethrough to operate as a water cooling heat sink. The water block is mounted on, and thermally coupled to, the heat-generating electronic component(s) (e.g., the processor of the server) via thermal interface materials (TIMs). TIMs manifest chemical properties that improve thermal conductivity and may take the form of inexpensive thermal pastes or expensive metal foils (e.g., Indium foil).

With this water block configuration, cooling water flows through the internal conduit of the water block to collect thermal energy from the electronic component(s). The collected thermal energy is then directed elsewhere to be dissipated or expelled, such as, for example, by external dry cooling unit(s).

However, in some situations, liquid cooling solely based on either liquid immersion systems or water cooling channeling systems may not be sufficient to effectively dissipate the heat from the heat-generating electronic component(s).

It is, therefore, desirable to efficiently improve the cooling capacity and applications of liquid cooling technologies.

### SUMMARY

It is an object of the present technology to ameliorate at least some of the shortcomings present in the prior art.

Developers have observed that combining liquid immersion systems with water cooling channeling systems may improve the overall liquid cooling effect on heat generating electronic component(s). However, as noted above, liquid immersion systems employ dielectric liquids, such as hydrocarbons or fluorocarbons. These dielectric liquids manifest properties that are chemical incompatible with the thermal interface materials (TIMS) typically used with the water blocks, but are compatible with metal foils, such as, Indium foil.

However, Indium foils are significantly more expensive than the conventional thermal pastes. For example, an Indium foil for a water block for cooling a CPU costs about 100 times more than conventional thermal paste. This may be cost prohibitive when considering widespread implementation for hundreds of thousands heat-generating components. There are also, there are concerns as to the sustainability of Indium, as it is a mined metal and a finite resource.

Developers of the present technology have addressed these above-noted problems with a solution that provides a water block that can be used in immersion cooling, in which contact between the immersion cooling liquid and the TIM is prevented. Therefore, chemically incompatible combinations of the immersion cooling liquid and the TIM can be implemented without the fear of a chemical breakdown of either material, as contact between the two is eliminated. Equally notable, the use of expensive Indium foils can be avoided.

Broadly speaking, the water block of the present technology provides a liquid-proof sealing of a surface on which the thermal paste is applied when the water block is mounted to an electronic component submerged in immersion cooling liquid. Moreover, the presented water block arrangement is configured to protect electronic components having both common and atypical surface area dimensions. As such, the present technology provides cost effective and sustainable enhanced cooling of electronic components for a wide variety of combined water block and immersion liquid implementations.

According to one aspect of the present technology, there is provided a liquid cooling device mountable on an electronic component submerged in an immersion cooling liquid including a cooling device body having a first surface disposed on a bottommost side of the cooling device for mounting onto an upper surface of the electronic component, the first surface configured with a open recess formed along an outer periphery of the first surface, a thermal interface material (TIM) interposed between the first surface and the upper surface of the electronic component (50) to promote the thermal transfer therebetween, a second surface disposed on an uppermost side of the cooling device and in parallel and opposite positioning to the first surface, an internal fluid conduit configured to internally channel a circulating flow of a heat-transfer fluid therethrough, at least one side wall extending between the first surface and the second surface, and a resiliently deformable gasket mounted on, and seated within, the open recess along the outer periphery of the first surface to provide a seal that fluidly insulates the first surface (110) from the immersion cooling liquid. The gasket is configured to deformably expand horizontally and/or vertically to establish a protective fluid-proof seal for the first surface of the cooling device body, the upper surface of the electronic component, and the TIM from the immersion cooling liquid.

In some embodiments, the liquid cooling device further comprises a second gasket mounted on a motherboard or socket and having an upper surface that interfaces with a bottom surface of the gasket to establish a protective fluid-proof seal from the immersion cooling liquid for a top surface of a motherboard or socket housing the electronic component and the first surface of the cooling device body, the upper surface of the electronic component, and the TIM.

In some other embodiments, the first and second gaskets have cross-sectional shapes comprising at least one of circular, oval, rectangular, and/or trapezoidal. Moreover, the first and second gaskets comprise a deformable elastomeric material that is resistant to immersion cooling liquid properties.

In additional embodiments, the deformable elastomeric material of the first and gaskets is configured to wedge into gaps between the cooling device body and the upper surface of the electronic component.

Embodiments of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Within the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Furthermore, the use of the phrase “at least one of A and B” is intended to mean A only, B only, or both A and B.

Moreover, unless expressly provided otherwise, the words “first”, “second”, “third”, etc. have been used as adjectives only for the purpose of allowing for distinction between the nouns that they modify from one another, and not for the purpose of describing any particular relationship between those nouns. It should also be understood that terms relating to the position and/or orientation of components such as “upper”, “lower”, “top”, “bottom”, “front”, “rear”, “left”, “right”, are used herein to simplify the description and are not intended to be limitative of the particular position/orientation of the components in use.

Additional and/or alternative features, aspects and advantages of embodiments of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 is a perspective view of a water block configuration, in accordance with embodiments of the present technology;

FIG. 2A is a bottom view and FIG. 2B is a side view of the water block configuration of FIG. 1 without a gasket, in accordance with embodiments of the present technology;

FIG. 3A is a bottom view and FIG. 3B is a side view of the water block configuration of FIG. 1 with a gasket, in accordance with embodiments of the present technology;

FIG. 4 is a cross-sectional view of a first mounting arrangement for connecting a water block to an electronic component installed in a motherboard, in accordance with embodiments of the present technology; and

FIG. 5 is a cross-sectional view of a second mounting arrangement for connecting a water block to an electronic component installed in a motherboard, in accordance with embodiments of the present technology; and

FIG. 6 is a cross-sectional view of a third mounting arrangement for connecting a water block to an electronic component installed in a motherboard, in accordance with embodiments of the present technology.

It is to be understood that, unless otherwise explicitly specified herein, the drawings are not necessarily rendered to scale. Moreover, the drawings may exaggerate or omit features in order to assist in the clear understanding of the disclosed embodiments.

### DETAILED DESCRIPTION

The present technology will be described herein with respect to the configuration of a water cooling device that internally channels cooling water and is mounted atop of a heat-generating electronic component of a motherboard submerged in dielectric immersion cooling liquid.

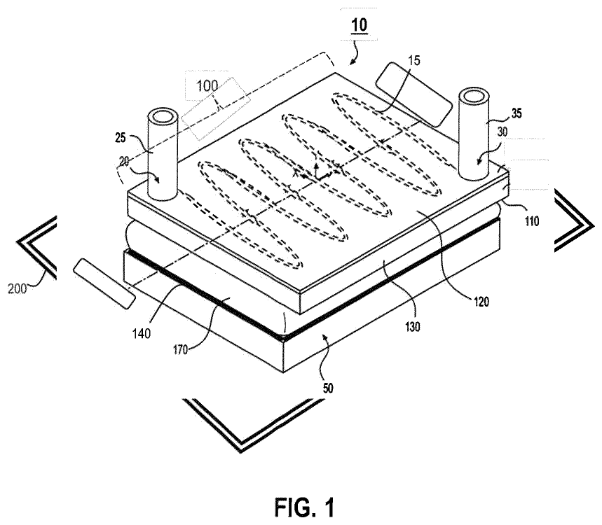

FIG. 1 depicts a perspective view of a water block 10 configuration, according to an embodiment of the present technology, in accordance with the embodiments of the present technology. As shown, the water block 10 comprises a body 100, a first (i.e., “lower”) surface 110, and a second (i.e., “upper”) surface 120. The lower surface 110 is parallelly arranged opposite to the second water block surface 120.

The water block body 100, lower surface 110, and second upper surface 120 are shown to manifest a generally square/rectangular shape defining four sidewalls 130 that extend vertically between the lower and upper surfaces 110, 120. It will be appreciated, however, that the depicted shapes of the water block body 100, lower and upper surfaces 110, 120 and sidewalls 130 are not intended to be limiting, as other shapes would be equally effective in view of the features of the present technology. For example, any one of the body 100 and lower and upper surfaces 110, 120 may comprise a circular, oval, or trapezoidal shape.

As noted above, water block 10 is configured to cool a heat-generating electronic component 50. The heat-generating electronic component 50 may comprise a central processing unit (CPU), a graphics processing unit (GPU), a microcontroller unit (MCU) or any heat-generating electronic component. In use, the heat-generating electronic component 50 is mounted to a motherboard 200 (e.g., printed circuit board (PCB)) or motherboard component socket. As will be described in further detail below, the water block 10, heat-generating electronic component 50, and motherboard/socket 200 are designed to be submerged in an immersion cooling liquid.

It will be appreciated that heat-generating electronic components 50 (e.g., CPUs, GPUs, MCUs, etc.) come in a variety of different sizes and/or shapes. In turn, the structural configurations of water block bodies 100 are designed to generally comport with the most common contact surface area dimensions used by heat-generating electronic components 50. However, to manufacture individual water block body 100 configurations that match atypical contact surface area dimensions would be cost-prohibitive and impractical. Therefore, as will be described in greater detail below, aspects of the present technology operate to mitigate this issue.

Returning to FIG. 1, water block 10 is arranged to be mounted atop of the heat-generating electronic component 50 for thermal contact via a thermal paste 140 therewith and to enable the water block 10 to absorb the heat generated by component 50. To this end, water block body 100 comprises an internal fluid conduit 15 for channeling and circulating cooling water therethrough. In turn, the upper surface 120 of water block 10 incorporates a fluid inlet 20 connected to an inlet pipe 25 that is in fluid communication with the internal fluid conduit 15 for receiving and forwarding the cooling water to the internal fluid conduit 15. Commensurately, the upper surface 120 also incorporates a fluid outlet 30 connected to an outlet pipe 35 that is in fluid communication with the internal fluid conduit 15 for receiving and discharging the water heated by the electronic component 50 from the internal fluid conduit 15.

In the illustrated embodiment, internal fluid conduit 15 is shown to manifest a serpentine configuration. However, it should be appreciated that the depicted shape of internal fluid conduit 15 is not intended to be limiting, as other configurations of the internal fluid conduit 15 have been contemplated that are equally effective based on the present technology.

As noted above, water block 10 is mounted atop of the heat-generating electronic component 50 for direct thermal transfer contact, via a thermal paste 140, in order for the internally circulating cooling water to absorb the heat generated by electronic component 50. The thermal paste 140 may be applied to the lower water block surface 110 in a manner that is known in the art, to ensure adequate heat transfer between an upper contact surface of the electronic component 50 and the lower surface 110.

The thermal paste 140 may comprise any suitable thermal paste which has adhesive and heat conducting properties. For example, thermal paste 140 may have a composition consisting of a bonding agent component and a particulate component. The particulate component may comprise particles of metal, minerals, and/or ceramics.

An aspect of the present technology addresses the issue that, while thermal pastes 140 are chemically incompatible with dielectric-based immersion cooling liquids containing hydrocarbons and/or fluorocarbons, the disclosed water block 10 configuration operates to sealably insulate any suitable thermal paste 140 from exposure to such immersion cooling liquids. Therefore, the need or use of cost-prohibitive TIMs that are chemically compatible to immersion cooling liquids, such as Indium foil, can be avoided for water blocks 10 submerged in dielectric-based immersion cooling liquids.

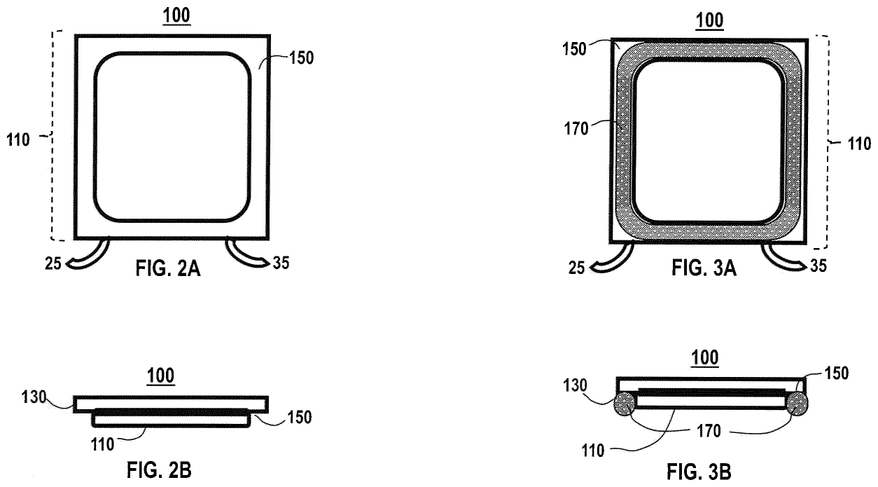

Turning back to FIG. 1, the water block 10 configuration depicts the use of a gasket 170. To this end, as best seen in FIGS. 2A, 2B, the lower surface 110 of water block body 100 is configured with a continuous, peripherally-surrounding open recess 150 that is sized and shaped to accommodate the seating and housing of gasket 170. The open recess 150 may be constructed or formed by any suitable manner. For example, recess 150 may be formed by milling by a numerically controlled milling machine, by molding equipment, or machining using electro-erosion techniques, etc.

The gasket 170 may be configured with any suitable cross-sectional profile. As shown in FIGS. 3A, 3B, gasket 170 is depicted as having a circular cross-sectional profile. However, in other embodiments, the cross-sectional profile of gasket 170 may comprise other shapes, such as, rectangular, oval, trapezoidal, etc.

The gasket 170 is comprised of a one piece construction and is sized and shaped to be fittingly seated and housed within the open recess 150. The gasket 170 is made of a material that is compatible with dielectric-based immersion cooling liquid as well as being resiliently deformable to enable dimensional expansion when compressed during installation. As such, gasket 170 may be made of an elastomeric material, such as chloroprene, fluorosilicone rubber, polytetrafluoroethylene (PTFE), fluoroelastomer, butadiene acylonitrile, or nitriles.

In other embodiments, gasket 170 may comprise an epoxy resin, which may be applied to recess 150 prior to polymerization as a liquid or a gel and allowed to polymerize in situ. The epoxy resin precursor may be applied to recess 150 after the water block 10 has been mounted on electronic component 50, so that it properly seals around the recess 150 and electronic component 50 when polymerized.

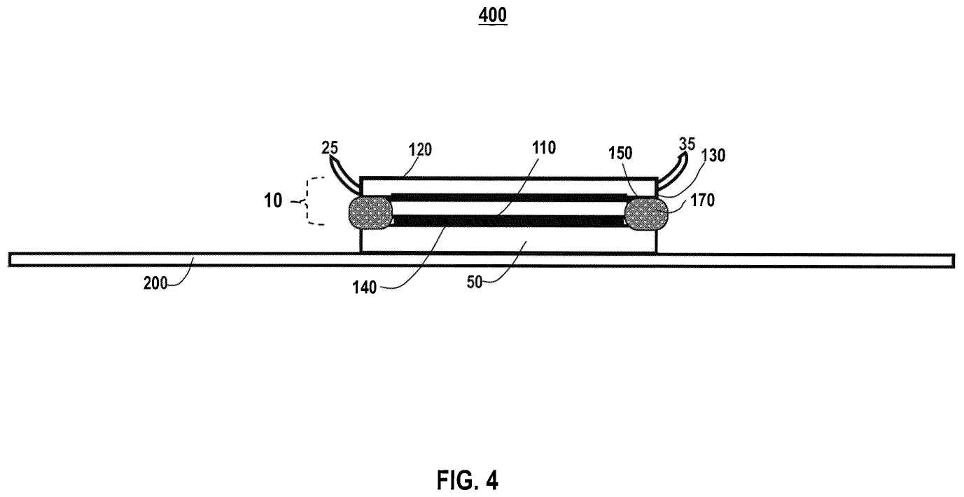

In view of the disclosures above, FIGS. 4, 5, 6 depict cross-sectional views of mounting arrangements 400, 500, 600 for the mounting of water block 10 onto electronic component 50 installed on motherboard/socket 200, in accordance with the embodiments of the present technology. It will be appreciated that attributes of the depicted features may be exaggerated for clarity and ease of understanding.

As noted above, water block body 100 configurations are generally designed to comport with the most common contact surface area dimensions of heat-generating electronic components 50. Accordingly, the depicted first mounting arrangement 400 of FIG. 4 is directed to the mounting of water block 10 that provides a fluid-proof seal to protect thermal paste 140 from immersion cooling liquid exposure for heat-generating electronic component 50 having common or typical contact surface area dimensions.

As shown, the mounting arrangement 400 provides for water block 10 to be mounted to electronic component 50, via thermal paste 140, such that the lower surface 110 of water block 10 and the applied thermal paste 140 are in direct thermal contact with the upper contact surface of electronic component 50.

The gasket 170 is seated within recess 150 of the lower surface 110 of water block 10 and, due to compression forces upon mounting water block 10 to electronic component 50, gasket 170 is configured to deform such that it outwardly expands (“bulges out”), along the horizontal direction, beyond the sidewall 130 edges and side edges of electronic component 50.

The outward horizontal expansion of gasket 170 enables the first mounting arrangement to establish a fluid-proof seal between the lower surface 110 of water block 10, the thermal paste 140, and the upper surface of electronic component 50, such that the thermal paste 140 is insulated and protected from any exposure to immersion cooling liquid.

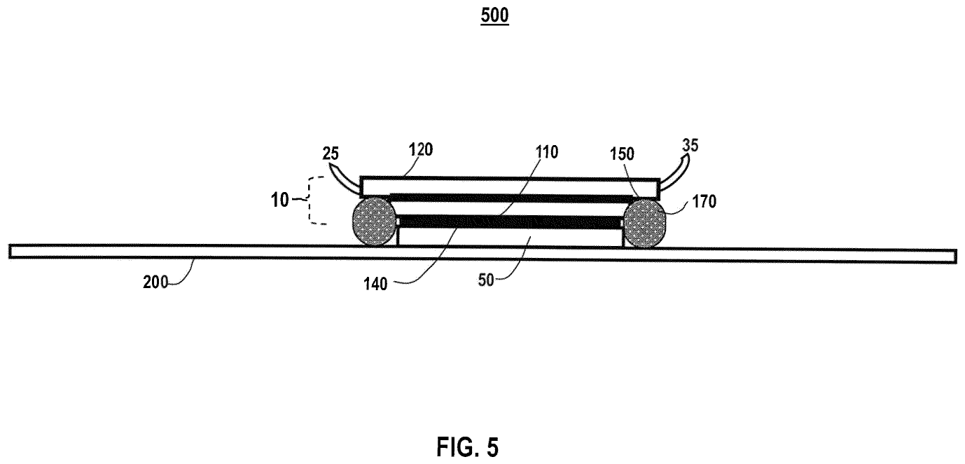

FIG. 5 depicts a cross-sectional view of a second mounting arrangement 500 for mounting water block 10 to electronic component 50 installed on motherboard/socket 200, in accordance with the embodiments of the present technology.

As noted above, water block body 100 configurations are generally designed to comport with the most common or typical contact surface area dimensions of heat-generating electronic components 50. However, it is neither cost effective nor practical to design different water block body 100 configurations to perfectly match typical contact surface area dimensions implemented by some heat-generating electronic components 50. Accordingly, the mounting arrangement 500 is directed to the mounting of water block 10 that provides a fluid-proof seal to protect thermal paste 140 from immersion cooling liquid for heat-generating electronic component 50 having an atypical shape (e.g., a trapezoidal shape).

The mounting arrangement 500 shares many of the aspects provided by the first mounting arrangement. Namely, the second mounting arrangement includes the mounting of the water block 10 onto the electronic component 50, via thermal paste 140, such that the lower surface 110 of water block 10 and the applied thermal paste 140 are in direct thermal contact with the upper contact surface of electronic component 50. Also, the gasket 170 is seated within recess 150 of the lower surface 110 of water block 10 and, due to compression forces upon mounting water block 10 to electronic component 50, gasket 170 is deformed to outwardly expand (“bulges out”), along the horizontal direction, beyond the sidewall 130 edges and side edges of electronic component 50.

However, unlike the first mounting arrangement 400, the second mounting arrangement 500 provides a fluid-proof seal to protect thermal paste 140 from immersion cooling liquid for heat-generating electronic components 50 having atypical contact surface area dimensions. That is, as indicated by FIG. 5, for the mounting arrangement 500, the gasket 170 is additionally configured to deform and expand along the vertical direction (“bulges down”) due to compression forces upon installation, to make a sealable contact with the surface of motherboard/socket 200.

As such, the second mounting arrangement provides the fluid-proof sealing of the water block lower surface 110, the thermal paste 140, and the upper surface of electronic component 50 along the horizontal and vertical directions for atypical electronic component 50 surface area dimensions.

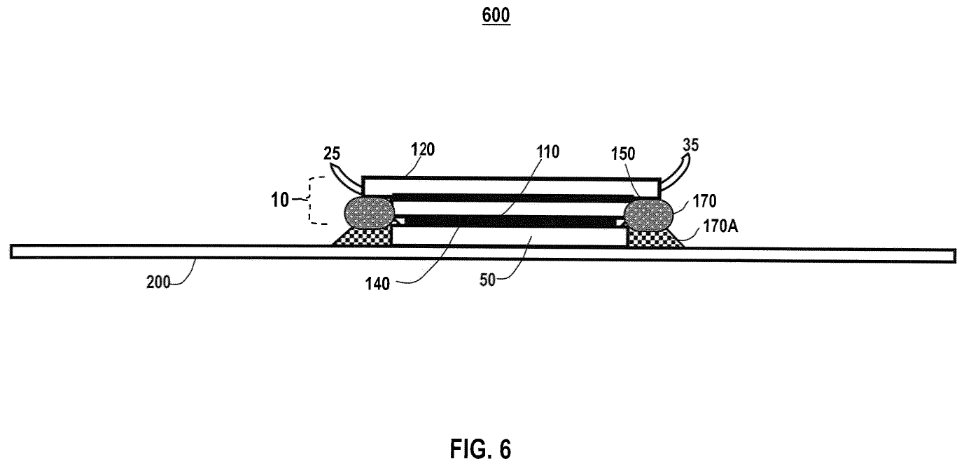

FIG. 6 depicts a cross-sectional view of a third mounting arrangement 600 for mounting water block 10 to electronic component 50 installed on motherboard/socket 200, in accordance with the embodiments of the present technology.

Like mounting arrangement 500, mounting arrangement 600 is directed to atypical contact surface area dimensions. However, mounting arrangement 600 incorporates a dual gasket 170, 170A implementation. That is, like mounting arrangement 400, mounting arrangement 600 employs a first gasket 170A having a circular cross-section that outwardly expands (“bulges out”), along the horizontal direction, due to mounting compression forces.

In addition, mounting arrangement 600 employs a second gasket 170A having a trapezoidal cross-section that is mounted on the motherboard/socket 200 having a top surface that interfaces with a bottom surface of first gasket 170. When two rubber gaskets 170, 170A are compressed, they fill any gaps or crevices between the surfaces, including for example, wedging into spaces between the water block lower surface 110 and the upper surface of electronic component 50, to block any leaks.

Because the elastomeric material is flexible, it adapts to uneven surfaces and stays effectively sealed even with movement or temperature changes. So, the idea of using two gaskets instead of one is to securely attach components with different geometries (water block and processor), with each gasket sealing against one component. This ensures a perfect fit and reliable sealing for both parts. Mounting arrangement 600, therefore, provides the fluid-proof sealing of the water block lower surface 110, the thermal paste 140, and the upper surface of electronic component 50 along the horizontal and vertical directions.

It will be appreciated that the capability of the disclosed water block 10 configuration to provide fluid-proof insulative sealing protection from the immersion cooling liquid properties for both, common and atypical surface area dimensions of electronic components 50 yields numerous technical and manufacturing advantages. For example, the disclosed water block 10 configuration achieves insulative protection for the water block lower surface 110, the thermal paste 140, and the upper surface of electronic component 50 for common and atypically-dimensioned electronic components 50 without the need for fabricating tailored water blocks for atypically-dimensioned electronic components 50.

Moreover, the disclosed water block 10 configuration mitigates the need for incorporating cost-prohibitive TIM materials, such as Indium, to provide protection against the immersion liquid properties.

In this manner, the disclosed embodiments of the present technology provide a liquid cooling device arrangement incorporating an open recess and a seated resiliently deformable gasket configured to horizontally or vertically expand to establish a fluid-proof seal that protects the TIM from immersion cooling liquids. As such, the present technology is capable or rendering cost effective and sustainable protection for a wide variety of combined water block and immersion liquid implementations.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A liquid cooling device mountable on an electronic component submerged in an immersion cooling liquid, the cooling device comprising:
a cooling device body comprising:
a first surface disposed on a bottommost side of the cooling device for mounting onto an upper surface of the electronic component, the first surface configured with a open recess formed along an outer periphery of the first surface;
a thermal interface material (TIM) interposed between the first surface and the upper surface of the electronic component to promote a thermal transfer therebetween;
a second surface disposed on an uppermost side of the cooling device and in parallel and opposite positioning to the first surface;
an internal fluid conduit configured to internally channel a circulating flow of a heat-transfer fluid therethrough;
at least one side wall extending between the first surface and the second surface; and
a resiliently deformable gasket mounted on, and seated within, the open recess along the outer periphery of the first surface to provide a seal that fluidly insulates the first surface from the immersion cooling liquid,
wherein the gasket is configured to deformably expand horizontally beyond the sidewall edges and side edges of electronic component to establish a protective fluid-proof seal for the first surface of the cooling device body, the upper surface of the electronic component, and the TIM from exposure to the immersion cooling liquid.

2. The liquid cooling device of claim 1, wherein the gasket is further configured to deformably expand vertically to establish a protective fluid-proof seal from the immersion cooling liquid for a top surface of a motherboard or socket housing the electronic component and the first surface of the cooling device body, the upper surface of the electronic component, and the TIM.

3. The liquid cooling device of claim 1 further comprising a second gasket mounted on a motherboard or socket and having an upper surface that interfaces with a bottom surface of the gasket to establish a protective fluid-proof seal from the immersion cooling liquid for a top surface of a motherboard or socket housing the electronic component and the first surface of the cooling device body, the upper surface of the electronic component, and the TIM.

4. The liquid cooling device of claim 1, wherein the first and second gaskets have cross-sectional shapes comprising at least one of circular, oval, rectangular, and/or trapezoidal.

5. The liquid cooling device of claim 4, wherein the first and second gaskets comprise a deformable elastomeric material that is resistant to, and/or compatible with, the immersion cooling liquid properties.

6. The liquid cooling device of claim 5 wherein, upon compression, the deformable elastomeric material of the first and second gaskets is configured to wedge into gaps between the cooling device body and the upper surface of the electronic component.

7. The liquid cooling device of claim 5, wherein the first and second gaskets deformable elastomeric material comprises at least one of: chloroprene, fluorosilicone rubber, polytetrafluoroethylene (PTFE), fluoroelastomer, butadiene acylonitrile, and/or nitriles.

8. The liquid cooling device of claim 3, wherein the first and second gaskets are comprised of a one-piece construction.

9. The liquid cooling device of claim 3, wherein the open recess of the first surface configured receive the first and second gaskets for mounting contain a general outline shape comprising one of a: square, rectangle, circle, oval, or trapezoid.

10. The liquid cooling device of claim 8, wherein the first and second gaskets contain a general outline shape for mounting onto the open recess that comprises one of a: square, rectangle, circle, oval, or trapezoid.

11. The liquid cooling device of claim 1, wherein the TIM comprises a thermal paste having a composition that incorporates a bonding component and a particulate component, wherein the particulate component comprises at least one of: metal particles, minerals, and/or ceramics.

12. The liquid cooling device of claim 11, wherein the TIM composition does not include Indium.

13. The liquid cooling device of claim 1, wherein the body further comprises a cold inlet to facilitate ingress flow of the heat-transfer fluid to the internal fluid conduit and a hot outlet to facilitate egress flow of the heat-transfer fluid from the internal fluid conduit.

14. The liquid cooling device of claim 13, wherein the internal fluid conduit comprises a serpentine-shaped configuration that is fluidly-coupled to the cold inlet and the hot outlet.

15. The liquid cooling device of claim 1, wherein the heat-transfer fluid comprises water.

16. The liquid cooling device of claim 1, wherein the immersion cooling liquid contains hydrocarbons and/or fluorocarbons.
